(19) United States
(12) Patent Application Publication
(10) Pub. No.: US 2013/0292797 A1
(43) Pub. Date: Nov. 7, 2013

(54) FULLY ENCAPSULATED CONDUCTIVE LINES

(71) Applicants: Nick Lindert, Beaverton, OR (US); Kanwal Jit Singh, Hillsboro, OR (US); Byung-Chan Lee, Portland, OR (US)

(72) Inventors: Nick Lindert, Beaverton, OR (US); Kanwal Jit Singh, Hillsboro, OR (US); Byung-Chan Lee, Portland, OR (US)

(21) Appl. No.: 13/977,542

(22) PCT Filed: Dec. 21, 2011
(86) PCT No.: PCT/US11/66495

§ 371 Date: Jun. 28, 2013

(51) Int. Cl. H01L 27/06; H01L 21/768

(52) U.S. Cl. CPC H01L 27/0611; H01L 21/76841
USPC 257/532; 438/381

(57) ABSTRACT

Fully encapsulated conductive lines are generally described. For example, a first dielectric layer is formed on a substrate. Copper wiring is disposed below a top surface of the first dielectric layer. A barrier metal layer is formed over the copper wiring, the barrier metal layer flush with the top surface of the first dielectric layer, and a second dielectric layer is formed on the barrier metal layer and the top surface of the first dielectric layer. Other embodiments are also disclosed and claimed.

### TECHNICAL FIELD

Embodiments of the invention are in the field of semiconductor structures and, in particular, fully encapsulated conductive lines.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, lending to the fabrication of products with increased capacity. The drive for ever-more capacity, however, is not without issue. The necessity to manufacture each device without even slight imperfections becomes increasingly significant.

In semiconductor devices with copper wiring, for example, two concerns are copper diffusion and copper electromigration. Copper diffusion, where copper diffuses with other adjacent materials can lead to electrical shorts, for example where copper diffuse through a thin dielectric layer. Copper electromigration, where copper can flow amongst itself for example around pinch points, can lead to electrical voids.

### BRIEF DESCRIPTION OF THE DRAWINGS

FIGS. 1A-1D are graphical illustrations of a cross-sectional view of an example conductive line in various stages of processing, in accordance with an embodiment of the present invention.

FIG. 2 is a graphical illustration of a cross-sectional view of an example fully encapsulated conductive line, in accordance with an embodiment of the present invention.

FIG. 3 is a graphical illustration of a cross-sectional view of an example fully encapsulated conductive line, in accordance with an embodiment of the present invention.

FIG. 4 is a flowchart of an example method of forming fully encapsulated conductive lines encapsulated, in accordance with an embodiment of the present invention.

FIG. 5 is a block diagram of an example electronic appliance suitable for fully encapsulated conductive lines, in accordance with an embodiment of the present invention.

### DETAILED DESCRIPTION

Fully encapsulated conductive lines are described. In the following description, numerous specific details are set forth, such as specific metal wiring layer counts and material regimes, in order to provide a thorough understanding of embodiments of the present invention. It will be apparent to one skilled in the art that embodiments of the present invention may be practiced without these specific details. In other instances, well-known features, such as integrated circuit design layouts, are not described in detail in order to not unnecessarily obscure embodiments of the present invention. Furthermore, it is to be understood that the various embodiments shown in the Figures are illustrative representations and are not necessarily drawn to scale.

Referring to FIGS. 1A-1D, graphical illustrations of a cross-sectional view of an example conductive line in various stages of processing, in accordance with an embodiment of the present invention, are presented. In device 100A, copper wiring 104 has been formed in a dielectric layer 102. In one embodiment, copper wiring 104 is formed by depositing a seed layer of metal, for example tantalum, onto the bottom and sidewalk of an opening created in dielectric layer 102 and then plating the seed layer with copper.

In device 100B, the height of copper wiring 104 has been lowered below top surface 106 of the dielectric layer using a copper wet etch. In one embodiment, the copper wet etch includes an etchant such as citric acid. In another embodiment, the copper wet etch also includes an oxidizing agent such as hydrogen peroxide, In another embodiment, the copper wet etch also includes a chelating passivator such as 1,2,3-Benzotriazol.

In device 1000, the dielectric layer has been covered by a deposition of barrier metal 108, In one embodiment, barrier metal 108 comprises tantalum, however alloys of tantalum or other suitable barrier metals may be used.

In device 100D, barrier metal 108 above top surface 106 has been removed. In one embodiment, mechanical polishing is used to planarize barrier metal 108 flush with top surface 106.

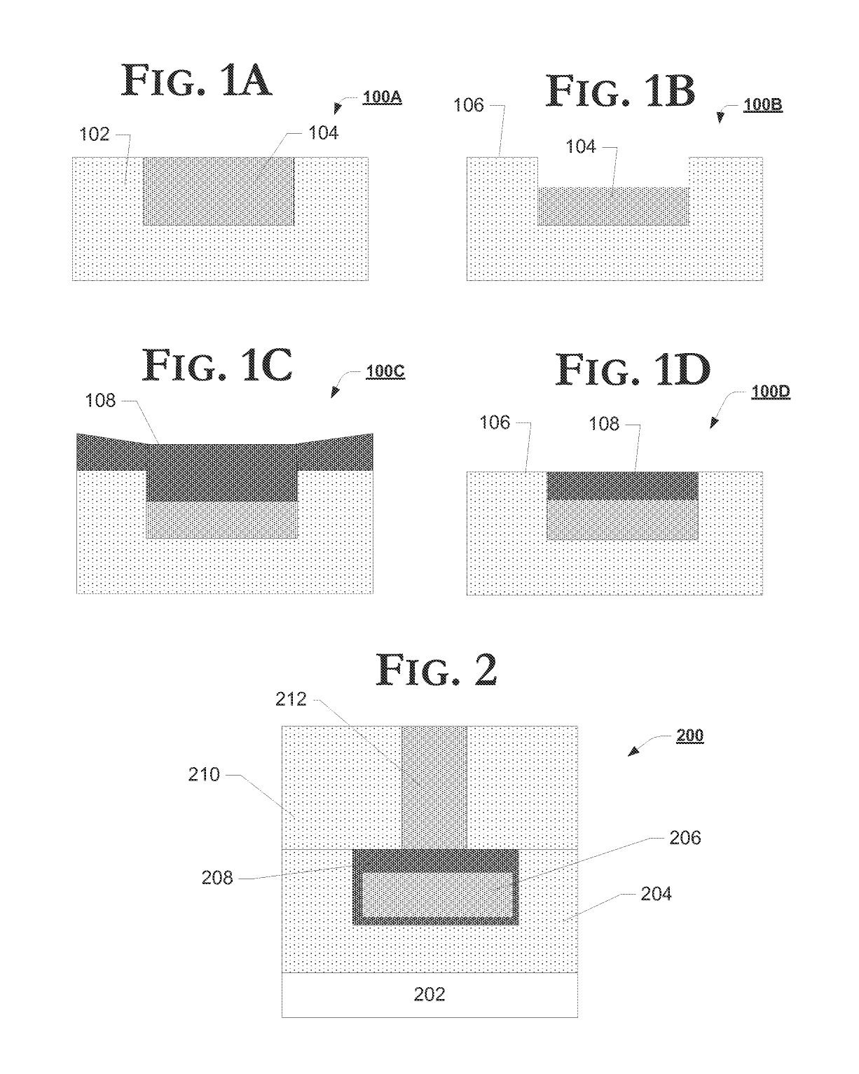

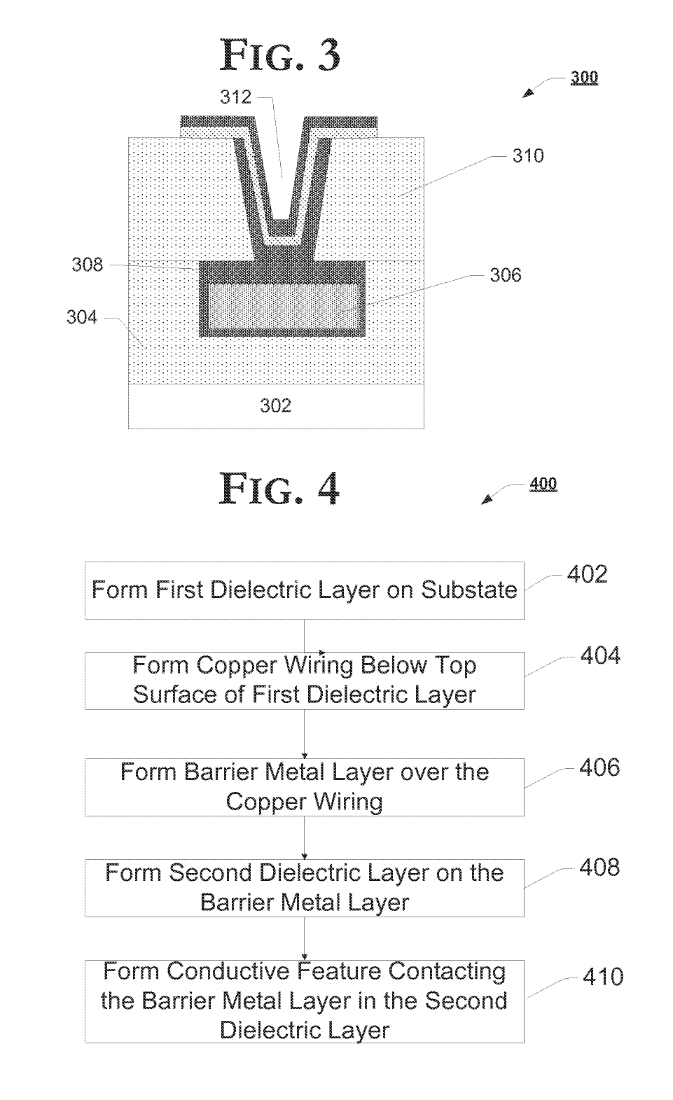

Referring to FIG. 2. a graphical illustration of a cross-sectional view of an example fully encapsulated conductive line, in accordance with an embodiment of the present invention, is presented. As shown, device 200 includes substrate 202, first dielectric layer 204, first copper wiring 206, barrier metal 208, second dielectric layer 210, and second copper wiring 212.

In an embodiment, substrate 202 is composed of a material suitable for semiconductor device fabrication. In one embodiment, substrate 202 is a bulk substrate composed of a single crystal of a material which may include, but is not limited to, silicon, germanium, silicon-germanium or a compound semiconductor material. In another embodiment, substrate 202 includes a bulk layer with a top epitaxial layer. In a specific embodiment, the bulk layer is composed of a single crystal of a material which may include, but is not limited to, silicon, germanium, silicon-germanium, a III-V compound semiconductor material or quartz, while the top epitaxial layer is composed of a single crystal layer which may include, but is not limited to, silicon, germanium, silicon-germanium or a compound semiconductor material. In another embodiment, substrate 202 includes a top epitaxial layer on a middle insulator layer which is above a lower bulk layer. The top epitaxial layer is composed of a single crystal layer which may include, but is not limited to, silicon (e.g., to form a silicon-on-insulator (SOI) semiconductor substrate), germanium, silicon-germanium or a III-V compound semiconductor material. The insulator layer is composed of a material which may include, but is not limited to, silicon dioxide, silicon nitride or silicon oxy-nitride. The lower hulk layer is composed of a single crystal which may include, but is not limited to, silicon, germanium, silicon-germanium, a III-V compound semiconductor material or quartz. Substrate 202 may further include dopant impurity atoms.

In accordance with an embodiment of the present invention, substrate 202 has thereon or therein an array of complementary metal-oxide-semiconductor (CMOS) transistors fabricated in a silicon substrate and encased in a dielectric layer. A plurality of metal interconnects may be formed above the transistors, and on a surrounding dielectric layer, and are used to electrically connect the transistors to form an integrated circuit.

In an embodiment, dielectric layers 204 and 210 are a low-K dielectric layer (a layer with a dielectric constant less than 4 for silicon dioxide). In one embodiment, dielectric layers 204 and 210 are formed by a process such as, but not limited to, a spin-on process, a chemical vapor deposition process, or a polymer-based chemical vapor deposition process. In a specific embodiment, dielectric layers 204 and 210 are formed by a chemical vapor deposition process involving silane or an organo-silane as a precursor gas. In an embodiment, dielectric layers 204 and 210 are composed of a material that does not significantly contribute to leakage current between a series of metal interconnects subsequently formed in or on dielectric layers 204 and 210. In one embodiment, dielectric layers 204 and 210 are composed of a material in the range of 2.5 to less than 4. In a particular embodiment, dielectric layers 204 and 210 are composed of a material such as, but not limited to, a silicate or a carbon-doped oxide with 0-10% porosity. In another embodiment, however, dielectric layers 204 and 210 are composed of silicon dioxide.

Copper wiring 206 and 212 may represent a via, another metal wiring, or an actual contact structure formed between a via and a semiconductor device. In an embodiment, at least a portion of the copper wiring 206 and 212 is electrically coupled to one or more semiconductor devices included in a logic circuit. Barrier metal 208 may fully encapsulate copper wiring 206 and conductively couple first copper wiring 206 with second copper wiring 212. In one embodiment, barrier metal 208 is tantalum. in another embodiment, barrier metal 208 is a combination of multiple metals.

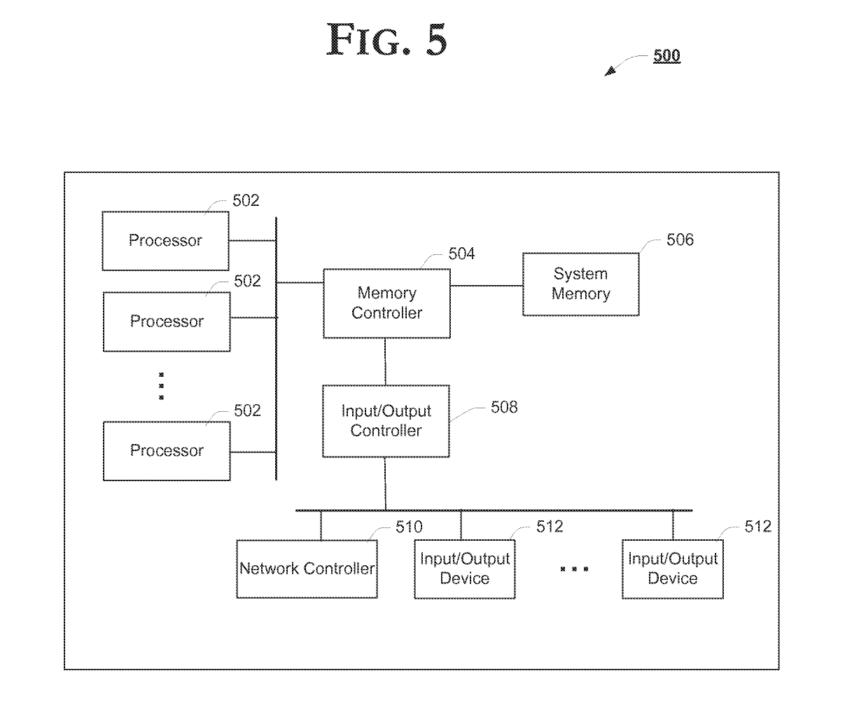

Referring to FIG. 3, a graphical illustration of a cross-sectional view of an example fully encapsulated conductive line, in accordance with an embodiment of the present invention, is presented. As shown, device 300 includes substrate 302, first dielectric layer 304, copper wiring 306, barrier metal 308, second dielectric layer 310, and metal-insulator-metal (MIM) capacitor 312.

In one embodiment, MIM capacitor 312 is formed in second dielectric layer 310 and coupled with barrier metal 308. in one embodiment, device 300 includes a transistor in substrate 302 and is used for a DRAM. One skilled in the art would appreciate that fully encapsulating copper wiring 306 with barrier metal 308 can prevent copper diffusion and electromigration.

FIG. 4 is a flowchart of an example method of forming fully encapsulated conductive lines encapsulated, in accordance with an embodiment of the present invention.

Referring to operation 402 of Flowchart 400, first dielectric layer is formed on substrate.

Referring to operation 404 of Flowchart 400, copper wiring is formed below a top surface of the first dielectric layer. In one embodiment, copper wiring is formed by depositing a seed metal on a bottom and sidewalls of an opening created through a top surface of the dielectric layer and then plating copper on the seed metal.

Referring to operation 406 of Flowchart 400, barrier metal is formed over the copper wiring. In an embodiment, this fully encapsulates the copper wiring. In one embodiment, tantalum is deposited over a top surface of the first dielectric layer and then polished down to be flush with the top surface.

Referring to operation 408 of Flowchart 400 a second dielectric layer is formed on the dielectric layer and the harrier metal layer.

Referring to operation 410 of Flowchart 400, a conductive feature is formed through the second dielectric layer in contact with the barrier metal. In one embodiment, the conductive feature is a copper wiring. In another embodiment, the conductive feature is a MIM capacitor.

In an embodiment, forming the MIM capacitor includes electrically coupling the MIM capacitor to one or more of the semiconductor devices. in one embodiment, forming the NUM capacitor includes forming an embedded dynamic random access memory (eDRAM) capacitor,

FIG. 5 is a block diagram of an example electronic appliance suitable for fully encapsulated conductive lines, in accordance with an embodiment of the present invention. Electronic appliance 500 is intended to represent any of a wide variety of traditional and non-traditional electronic appliances, laptops, cell phones, wireless communication subscriber units, personal digital assistants, or any electric appliance that would benefit from the teachings of the present invention. In accordance with the illustrated example embodiment, electronic appliance 500 may include one or more of processor(s) 502, memory controller 504, system memory 506, input/output controller 508, network controller 510, and input/output device(s) 512 coupled as shown in FIG. 5. One or more components of electronic appliance 500 (for example, processor(s) 502 or system memory 506) may include fully encapsulated conductive lines described previously as an embodiment of the present invention.

Processor(s) 502 may represent any of a wide variety of control logic including, but not limited to one or more of a microprocessor, a programmable logic device (PLD), programmable logic array (PEA), application specific integrated circuit (ASIC), a microcontroller, and the like, although the present invention is not limited in this respect. In one embodiment, processors(s) 502 are Intel® compatible processors. Processor(s) 502 may have an instruction set containing a plurality of machine level instructions that may be invoked, for example by an application or operating system.

Memory controller 504 may represent any type of chipset or control logic that interfaces system memory 506 with the other components of electronic appliance 500. in one embodiment, the connection between processor(s) 502 and memory controller 504 may be a high speed/frequency serial link including one or more differential pairs, In another embodiment, memory controller 504 may be incorporated into processor(s) 502 and differential pairs may directly connect processor(s) 502 with system memory 506.

System memory 506 may represent any type of memory device(s) used to store data and instructions that may have been or will be used by processor(s) 502. Typically, though the invention is not limited in this respect, system memory 506 will consist of dynamic random access memory (DRAM). In one embodiment, system memory 506 may consist of Rambus DRAM (RDRAM). In another embodiment, system memory 506 may consist of double data rate synchronous DRAM (DDRSDRAM).

Input/output (I/O) controller 508 may represent any type of chipset or control logic that interfaces I/O device(s) 512 with the other components of electronic appliance 500. in one embodiment, 110 controller 508 may be referred to as a south bridge. In another embodiment, I/O controller 508 may comply with the Peripheral Component Interconnect (PCI) Express™ Base Specification, Revision 1.0a, PCI Special Interest Group, released Apr. 15, 2003.

Network controller 510 may represent any type of device that allows electronic appliance 500 to communicate with other electronic appliances or devices. in one embodiment, network controller 510 may comply with a The Institute of Electrical and Electronics Engineers, Inc. (IEEE) 802.11b standard (approved Sep. 16, 1999, supplement to ANSI/IEEE Std 802.11, 1999 Edition). In another embodiment, network controller 510 may be an Ethernet network interface card.

Input/output (110) device(s) 512 may represent any type of device, peripheral or component that provides input to or processes output from electronic appliance 500.

It is to be understood that even though numerous characteristics and advantages of various embodiments of the present invention have been set forth in the foregoing description, together with details of the structure and function of various embodiments of the invention, this disclosure is illustrative only. In some cases, certain subassemblies are only described in detail with one such embodiment. Nevertheless, it is recognized and intended that such subassemblies may be used in other embodiments of the invention. Changes may be made in detail, especially matters of structure and management of parts within the principles of the embodiments of the invention to the full extent indicated by the broad general meaning of the terms in which the appended claims are expressed.

Having disclosed exemplary embodiments and the best mode, modifications and variations may be made to the disclosed embodiments while remaining within the scope of the embodiments of the invention as defined by the following claims.

What is claimed is:

1. A method, comprising:
forming a first dielectric layer on a substrate;
forming copper wiring below a top surface of the first dielectric layer;
forming a barrier metal layer over the copper wiring, the barrier metal layer flush with the top surface of the first dielectric layer; and
forming a second dielectric layer on the barrier metal layer and the top surface of the first dielectric layer.

2. The method of claim 1, further comprising forming a metal-insulator-metal (MIM) capacitor in the second dielectric layer, the MIM capacitor coupled with the barrier metal layer.

3. The method of claim 1, further comprising forming copper wiring in the second dielectric layer, the copper wiring coupled with the barrier metal layer.

4. The method of claim 1, wherein forming copper wiring below a top surface of the first dielectric layer comprises:
forming an opening having a bottom and sidewalk through the top surface of first dielectric layer;
depositing seed layers of a barrier metal on the bottom and sidewalk;
plating the opening with copper; and
performing a copper wet etch to lower the height of the copper below the top surface of the first dielectric layer.

5. The method of claim 4, wherein performing a copper wet etch comprises a citric acid etchant.

6. The method of claim 4, wherein performing a copper wet etch comprises an oxidizing agent.

7. The method of claim 4, wherein performing a copper wet etch comprises a chelating passivator.

8. The method of claim 1, wherein forming a barrier metal layer over the copper wiring comprises:
depositing tantalum in an area over the copper wiring created by a copper wet etch; and
polishing the tantalum to planarize with the top surface of the first dielectric layer.

9. A semiconductor structure, comprising:
a first dielectric layer disposed on a substrate;
copper wiring below a top surface of the first dielectric layer;
a barrier metal layer over at least a portion of the copper wiring, the barrier metal layer flush with the top surface of the first dielectric layer; and
a second dielectric layer on the barrier metal layer and e top surface of the first dielectric layer.

10. The semiconductor structure of claim 9, further comprising a metal-insulator-metal (MIM) capacitor in the second dielectric layer, the MIM capacitor coupled with the barrier metal layer.

11. The semiconductor structure of claim 10, wherein the capacitor is part of an embedded dynamic random access memory (eDRAM).

12. The semiconductor structure of claim 9, further comprising a copper wiring in the second dielectric layer, the copper wiring coupled with the barrier metal layer.

13. The semiconductor structure of claim 9, wherein barrier metal layer comprises tantalum.

14. The semiconductor structure of claim 13, further comprising a tantalum layer on a side of the copper wiring.

15. An apparatus, comprising:
a plurality of semiconductor devices disposed in or above a substrate;
a first dielectric layer disposed above the plurality of semiconductor devices;
copper wiring below a top surface of the first dielectric layer and electrically coupled to one or more of the semiconductor devices;
a barrier metal layer over at least a portion of the copper wiring, the barrier metal layer flush with the top surface of the first dielectric layer; and
a second dielectric layer on the barrier metal layer and the top surface of the first dielectric layer.

16. The apparatus of claim 15, further comprising a metal-insulator-metal (MIM) capacitor in the second dielectric layer, the MIM capacitor coupled with the barrier metal layer.

17. The apparatus of claim 16, wherein the MIM capacitor is part of an embedded dynamic random access memory (eDRAM).

18. The apparatus of claim 15, further comprising a copper wiring in the second dielectric layer, the copper wiring coupled with the barrier metal layer.

19. The apparatus of claim 15, wherein barrier metal layer comprises tantalum.

20. The apparatus of claim 19, further comprising a tantalum layer on a side of the copper wiring.
